(19) United States
(12) Patent Application Publication
(10) Pub. No.: US 2024/0429295 A1
(43) Pub. Date: Dec. 26, 2024

(54) GALLIUM NITRIDE-BASED DEVICE AND METHOD FOR MANUFACTURING THE SAME

(71) Applicant: XIAMEN SAN'AN INTEGRATED CIRCUIT CO., LTD., Xiamen (CN)

(72) Inventors: Dongpo CHEN, Xiamen (CN); Shenghou LIU, Xiamen (CN); Yong ZENG, Xiamen (CN)

(21) Appl. No.: 18/824,475

(22) Filed: Sep. 4, 2024

Related U.S. Application Data
(63) Continuation-in-part of application No. PCT/CN2024/080084, filed on Mar. 5, 2024.

(30) Foreign Application Priority Data
Mar. 28, 2023 (CN) 202310312977.6

(51) Int. Cl. H01L 29/417; H01L 29/20; H01L 29/40; H01L 29/423

(52) U.S. Cl. CPC H01L 29/41775; H01L 29/2003; H01L 29/407; H01L 29/42364; H01L 29/42376

(57) ABSTRACT

A method for manufacturing a gallium nitride-based device includes: forming an epitaxial layer on a substrate, forming a source electrode and a drain electrode spaced apart from each other on the epitaxial layer, and forming a first dielectric layer between the source electrode and the drain electrode on the epitaxial layer; forming a second dielectric layer on the first dielectric layer, the second dielectric layer covering the source electrode and the drain electrode; etching the first dielectric layer and the second dielectric layer, so as to simultaneously form a gate receiving groove and a field plate receiving groove that expose the epitaxial layer between the source electrode and the drain electrode; forming a gate electrode in the gate receiving groove; and forming a field plate in the field plate receiving groove, the field plate being insulated from the epitaxial layer. A gallium nitride-based device is also provided.

### CROSS-REFERENCE TO RELATED APPLICATION

This application is a continuation-in-part (CIP) of International Application No. PCT/CN2024/080084, filed on Mar. 5, 2024, which claims priority to Chinese Invention patent application No. 202310312977.6, filed on Mar. 28, 2023. The aforesaid applications are incorporated by reference herein in their entirety.

### FIELD

The disclosure relates to a semiconductor device and a method for manufacturing the same, and more particularly to a gallium nitride-based device and a method for manufacturing the same.

### BACKGROUND

Gallium nitride (GaN), as a third-generation semiconductor material, has a very high critical breakdown electric field (approximately 3.3 MV/cm), so theoretically, a GaN-based device is supposed to have a high breakdown voltage. However, in reality, a GaN high electron mobility transistor (HEMT) device made of GaN has a breakdown voltage that is much lower than a theoretical value thereof. The reasons for the occurrence of a premature breakdown in the GaN HEMT device may include that a maximum electric field of the GaN HEMT device is often generated at a drain-side of a gate electrode, resulting in an electric field concentration in the gate electrode and uneven electric field distribution.

In recent years, the simplest way to solve the problem of the electric field concentration in the gate electrode is to use a field plate, so as to increase a breakdown voltage of the GaN-based device and decrease an electronic effect under a strong electric field, thereby suppressing the current collapse as well as increasing the output power density. Nevertheless, a conventional GaN-based device with such field plate disposed in a groove thereof is confronted with problems of having complicated manufacturing processes and the occurrence of a misalignment between the field plate in the groove and a gate electrode thereof. In view of the aforesaid, it is significant to provide a new method for manufacturing a GaN-based device to solve the abovementioned problems.

### SUMMARY

Therefore, an object of the disclosure is to provide a gallium nitride-based device and a method for manufacturing the same that can alleviate at least one of the drawbacks of the prior art.

According to a first aspect of the disclosure, the method includes the steps of:
(a) forming an epitaxial layer on a substrate, forming a source electrode and a drain electrode spaced apart from each other on the epitaxial layer, and forming a first dielectric layer between the source electrode and the drain electrode on the epitaxial layer;
(b) forming a second dielectric layer on the first dielectric layer, the second dielectric layer covering the source electrode and the drain electrode;
(c) etching the first dielectric layer and the second dielectric layer, so as to simultaneously form a gate receiving groove and a field plate receiving groove that expose the epitaxial layer between the source electrode and the drain electrode, the gate receiving groove being disposed between the source electrode and the field plate receiving groove;
(d) forming a gate electrode in the gate receiving groove; and
(e) forming a field plate in the field plate receiving groove, the field plate being insulated from the epitaxial layer.

According to a second aspect of the disclosure, the gallium nitride-based device includes a substrate, an epitaxial layer disposed on the substrate, a source electrode and a drain electrode disposed on the epitaxial layer and spaced apart from each other, a gate electrode disposed on the epitaxial layer and between the source electrode and the drain electrode, a first dielectric layer disposed on the epitaxial layer, isolating the source electrode from the gate electrode, and isolating the gate electrode from the drain electrode, a second dielectric layer disposed on the first dielectric layer and covering the source electrode and the drain electrode, and a field plate disposed between the gate electrode and the drain electrode. In addition, the gate electrode is exposed from the second dielectric layer. The second dielectric layer and the first dielectric layer cooperatively define a field plate receiving groove that extends through the second dielectric layer and the first dielectric layer to expose the epitaxial layer. The field plate receiving groove is disposed between the gate electrode and the drain electrode. The field plate is disposed in the field plate receiving groove and sinks into the field plate receiving groove to form a field plate recess. The field plate is insulated from the epitaxial layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 shows a flow chart illustrating an embodiment of a method for manufacturing a gallium nitride-based device according to the disclosure.

FIG. 2 shows a flow chart illustrating step (d) of the method for manufacturing the gallium nitride-based device according to the disclosure.

FIG. 3 shows a flow chart illustrating step (e) of the method for manufacturing the gallium nitride-based device according to the disclosure.

FIG. 4 is a schematic view illustrating step (a) of the method for manufacturing the gallium nitride-based device according to the disclosure.

FIG. 5 is a schematic view illustrating step (b) of the method for manufacturing the gallium nitride-based device according to the disclosure.

FIG. 6 is a schematic view illustrating step (c) of the method for manufacturing the gallium nitride-based device according to the disclosure.

FIG. 7 is a schematic view illustrating step (d1) of the method for manufacturing the gallium nitride-based device according to the disclosure.

FIG. 8 is a schematic view illustrating step (d2) of the method for manufacturing the gallium nitride-based device according to the disclosure.

FIG. 9 is a schematic view illustrating step (e1) of the method for manufacturing the gallium nitride-based device according to the disclosure.

FIG. 10 is a schematic view illustrating step (e2) of the method for manufacturing the gallium nitride-based device according to the disclosure.

FIG. 11 is a schematic view illustrating an embodiment of the gallium nitride-based device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

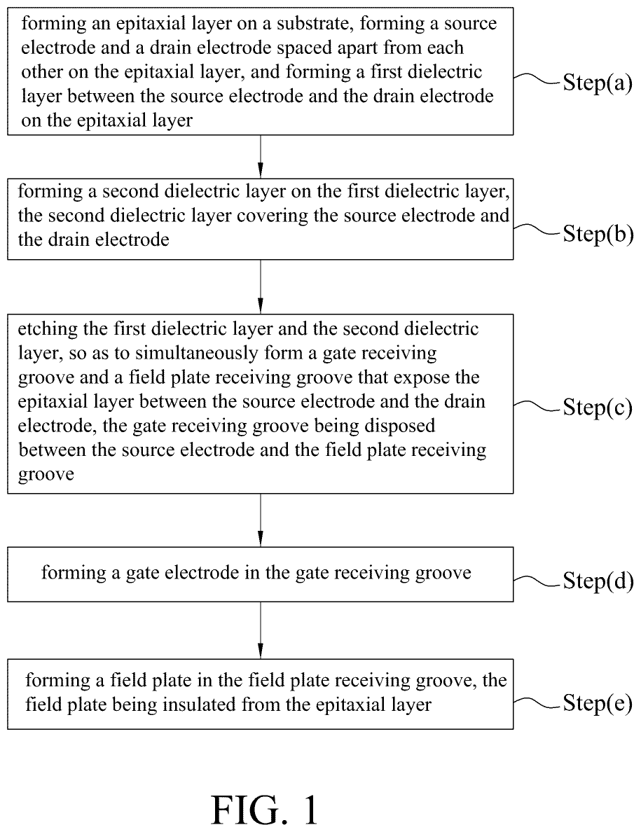

Referring to FIG. 1, in this embodiment, a method for manufacturing a gallium nitride-based device is provided. The method includes the steps as follows.

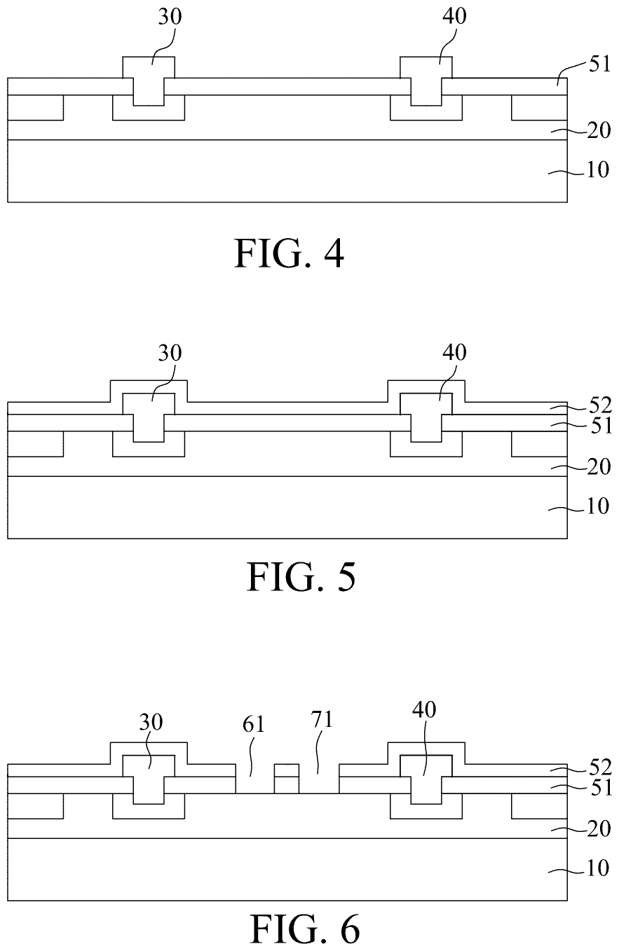

Referring to FIG. 4, in step (a), an epitaxial layer 20 is formed on a substrate 10, and then a source electrode 30 and a drain electrode 40 that are spaced apart from each other are formed on the epitaxial layer 20. Subsequently, a first dielectric layer 51 disposed between the source electrode 30 and the drain electrode 40 is formed on the epitaxial layer 20.

As shown in FIG. 4, the epitaxial layer 20 is disposed on the substrate 10, the source electrode 30 and the drain electrode 40 are disposed on the epitaxial layer 20, and the first dielectric layer 51 is disposed on the epitaxial layer 20 and insulates the source electrode 30 and the drain electrode 40 from each other.

The substrate 10 may be a silicon substrate, a silicon carbide substrate, a sapphire substrate, etc. The epitaxial layer 20 includes a nucleation layer, a buffer layer, a barrier layer, and a cap layer. Material selections and thicknesses of the nucleation layer, the buffer layer, the barrier layer, and the cap layer are within the expertise of those skilled in the art, and therefore are not limited in the present disclosure. The epitaxial layer 20 includes at least one barrier layer and at least one gallium nitride (GaN) layer that cooperatively form a heterojunction.

In addition, the technique for forming the source electrode 30 or the drain electrode 40 is also within the expertise of those skilled in the art. For example, the source electrode 30 and the drain electrode 40 may be formed by a vapor deposition technique. Each of the source electrode 30 and the drain electrode 40 may have a stacked structure, and the stacked structure may include, for instance, a titanium layer, an aluminum layer, a nickel layer, and a gold layer stacked sequentially in that order.

In this embodiment, the first dielectric layer 51 has a thickness that ranges from 1 nm to 150 nm. For example, the thickness may be, but not limited to, 1 nm, 10 nm, 50 nm, 100 nm, or 150 nm.

Referring to FIG. 5, in step (b), a second dielectric layer 52 is formed on the first dielectric layer 51. The second dielectric layer 52 covers the source electrode 30 and the drain electrode 40.

In this embodiment, the second dielectric layer 52 is formed on the first dielectric layer 51 by a plasma-enhanced chemical vapor deposition method. As shown in FIG. 5, the second dielectric layer 52 not only covers the first dielectric layer 51, but also covers the source electrode 30 and the drain electrode 40 that are exposed from the first dielectric layer 51.

In this embodiment, a material of the second dielectric layer 52 may be silicon nitride (SiN), silicon oxide (SiO), silicon oxynitride (SiON), aluminum oxide (AlO), aluminum nitride (AlN), or aluminum oxynitride (AlON). In addition, the second dielectric layer 52 may have a thickness ranging from 1 nm to 150 nm. For example, the thickness may be, but not limited to 1 nm, 10 nm, 50 nm, 100 nm, or 150 nm.

In this embodiment, a sum of the thickness of the first dielectric layer 51 and the thickness of the second dielectric layer 52 is controlled to be less than or equal to 150 nm. The smaller the sum of the thicknesses of the first dielectric layer 51 and the second dielectric layer 52, the better the controllability of a gate electrode 60 (see FIG. 8) subsequently formed; however, parasitic capacitance of the gate electrode 60 may become larger, which results in degradation of radio-frequency performance. In contrast, the greater the sum of the thicknesses, the smaller the parasitic capacitance of the gate electrode 60; however, the controllability of the gate electrode 60 is reduced, and a peak electric field of the gallium nitride-based device is increased, which affects the reliability of the gallium nitride-based device. Therefore, in order to allow the gallium nitride-based device to achieve better performance, the sum of the thicknesses of the first dielectric layer 51 and the second dielectric layer 52 may be controlled to be approximately 150 nm.

Referring to FIG. 6, in step (c), the first dielectric layer 51 and the second dielectric layer 52 are etched, so as to simultaneously form a gate receiving groove 61 and a field plate receiving groove 71 that expose the epitaxial layer 20 between the source electrode 30 and the drain electrode 40. The gate receiving groove 61 is located between the source electrode 30 and the field plate receiving groove 71.

It should be noted that, in step (c), simultaneously forming the gate receiving groove 61 and the field plate receiving groove 71 can be achieved by using a same photomask. Compared with a conventional etching process in which only one groove can be obtained after etching, in the present disclosure, the gate receiving groove 61 and the field plate receiving groove 71 are simultaneously formed by an etching process using the same photomask, which not only simplifies the manufacturing process but also reduces production cost.

To be specific, initially, a desired pattern is made on a photomask by a photolithography process, and then the second dielectric layer 52 and the first dielectric layer 51 are subjected to a dry etching process using the patterned photomask and a photoresist until the epitaxial layer 20 is exposed (specifically, the exposure of the cap layer or the barrier layer of the epitaxial layer 20). After the photoresist is removed, a structure shown in FIG. 6 is obtained.

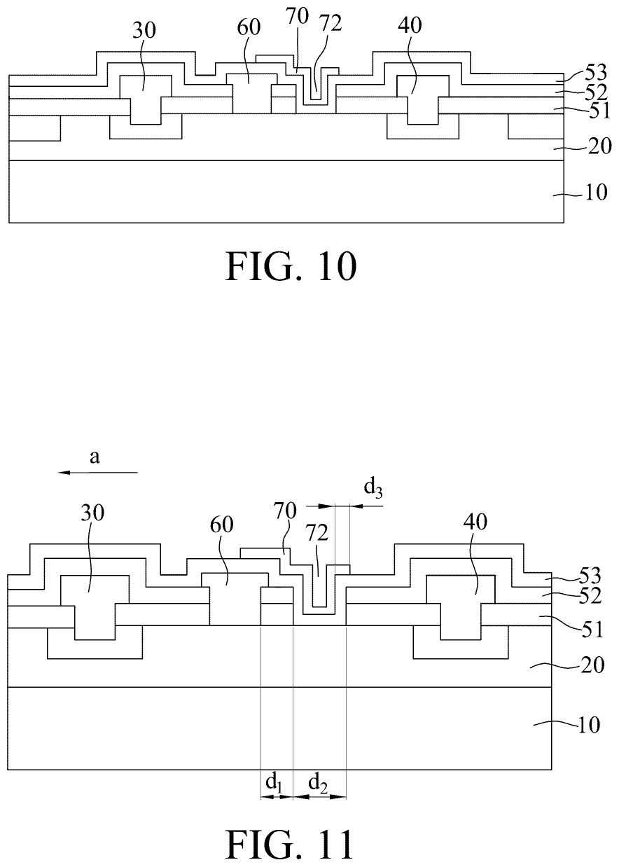

In the present disclosure, since the gate receiving groove 61 and the field plate receiving groove 71 are produced using the above-mentioned process, a distance between the gate receiving groove 61 and the field plate receiving groove 71 can be determined by a corresponding distance designed on the patterned photomask; that is to say, such distance therebetween is not relevant to an alignment offset that occurs during photolithography. In this way, the distance between the gate receiving groove 61 and the field plate receiving groove 71 can be stably controlled, so that a distance between the gate electrode 60 and a field plate 70 (see FIG. 10) can hence be accurately controlled.

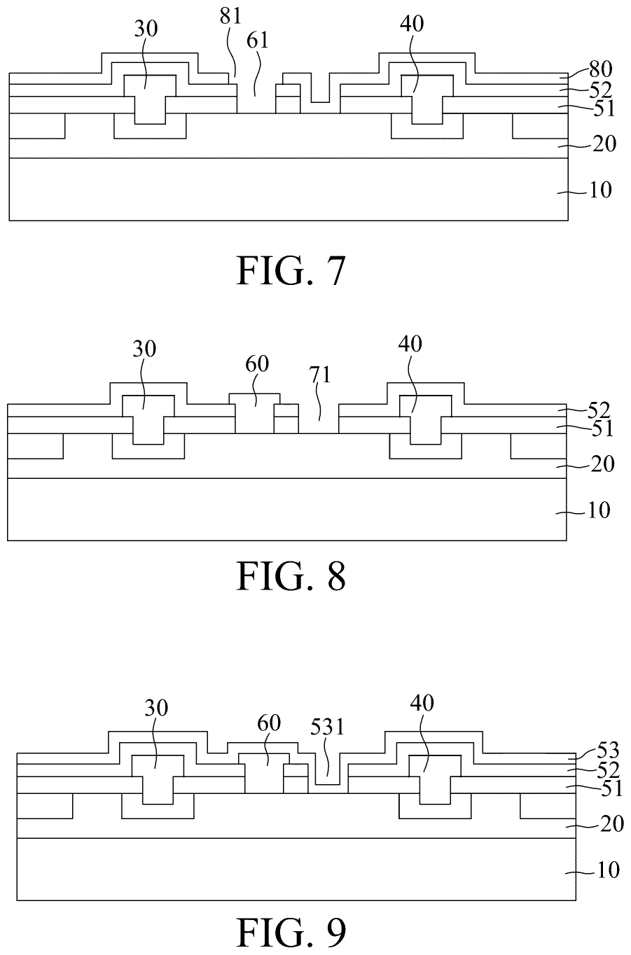

Referring to FIG. 8, in step (d), the gate electrode 60 is formed in the gate receiving groove 61 (see FIG. 7).

In certain embodiments, the gate electrode 60 may be a stacked structure, and the stacked structure may include a nickel layer and a gold layer disposed on the nickel layer.

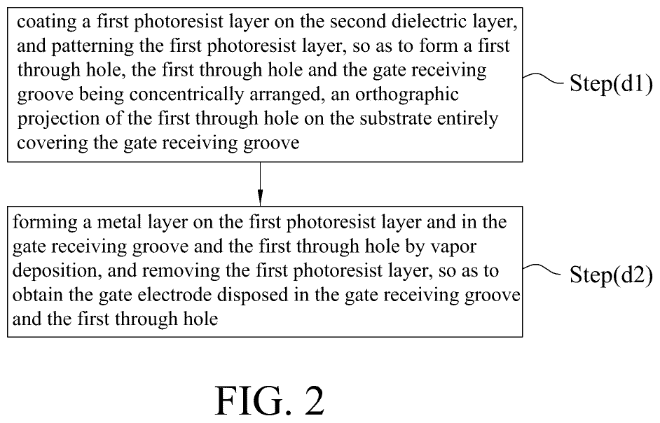

Referring to FIG. 2, in step (d) of this embodiment, forming the gate electrode 60 in the gate receiving groove 61 can be implemented through the steps as follows.

Referring to FIG. 7, in step (d1), a first photoresist layer 80 is coated on the second dielectric layer 52, followed by patterning the first photoresist layer 80, so as to form a first through hole 81. The first through hole 81 and the gate receiving groove 61 are concentrically arranged, and an orthographic projection of the first through hole 81 on the substrate 10 entirely covers the gate receiving groove 61.

The first through hole 81 extends through the first photoresist layer 80 and is concentrically arranged with the gate receiving groove 61. Additionally, the orthographic projection of the first through hole 81 on the substrate 10 covers the gate receiving groove 61. However, the first through hole 81 is greater in size than the gate receiving groove 61, and as such, the gate electrode 60 subsequently formed has a T-shaped cross-section as shown in FIG. 8.

The size of the first through hole 81 may be designed as desired by those skilled in the art based on a size of the gate electrode 60 to be formed, and is not particularly limited in the present disclosure.

Referring to FIG. 8, in step (d2), a metal layer is formed on the first photoresist layer 80 and in the gate receiving groove 61 and the first through hole 81 by vapor deposition, followed by removing the first photoresist layer 80, so as to obtain the gate electrode 60 disposed in the gate receiving groove 61 and the first through hole 81 (see FIG. 7).

Specifically, the metal layer is formed by vapor deposition on an entire surface of the first photoresist layer 80, and at this time, a portion of the metal layer is deposited in the first through hole 81 and the gate receiving groove 61. After completion of vapor deposition, the first photoresist layer 80 with the metal layer thereon is removed by a stripping process, thereby obtaining the gate electrode 60 as shown in FIG. 8.

Referring to FIG. 10, in step (e), the field plate 70 is formed in the field plate receiving groove 71 (see FIG. 8), and the field plate 70 is insulated from the epitaxial layer 20.

In certain embodiments, the field plate 70 may be a stacked structure, and the stacked structure may sequentially include a first titanium layer, a platinum layer, a gold layer, and a second titanium layer. The thickness of the field plate 70 is not particularly limited in the present disclosure.

It should be noted that field plate 70 may be used as a source field plate or a gate field plate. When the field plate 70 serves as the source field plate, it should be electrically connected to the source electrode 30. In some embodiments, electrical connection of the field plate 70 (serving as the source field plate) to the source electrode 30 may be achieved using a metal layer. When the field plate 70 serves as the gate field plate, it should be electrically connected to the gate electrode 60. In some embodiments, electrical connection of the field plate 70 (serving as the gate field plate) to the gate electrode 60 may be achieved using a metal layer.

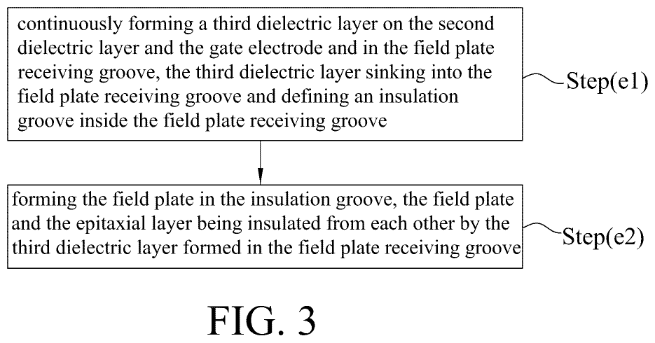

Referring to FIG. 3, in step (e) of this embodiment, forming the field plate 70 in the field plate receiving groove 71 can be implemented through the steps as follows.

Referring to FIG. 9, in step (e1), a third dielectric layer 53 is continuously formed on the second dielectric layer 52 and the gate electrode 60 and in the field plate receiving groove 71. The third dielectric layer 53 sinks into the field plate receiving groove 71 and defines an insulation groove 531 inside the field plate receiving groove 71.

That is to say, the third dielectric layer 53 covers the second dielectric layer 52 and the gate electrode 60 that is exposed from the second dielectric layer 52, and is also deposited in the field plate receiving groove 71. Specifically, the third dielectric layer 53 is deposited on a side wall surface and a bottom surface of the field plate receiving groove 71. A portion of the third dielectric layer 53 that is deposited on the side wall surface and the bottom surface of the field plate receiving groove 71 defines the insulation groove 531.

In this embodiment, the third dielectric layer 53 may have a thickness ranging from 30 nm to 300 nm.

The reason why the thickness of the third dielectric layer 53 is designed to range from 30 nm to 300 nm is as follows. When the thickness of the third dielectric layer 53 is less than 30 nm, not only may a breakdown of the gate electrode 60 and the field plate 70, or a serious electrical leakage occur, but exceedingly large capacitance Cgs between the gate electrode 60 and the source electrode 30 (the source electrode 30 connected to the field plate 70) may also develop, resulting in a deterioration in radio-frequency performance of the gallium nitride-based device. When the thickness of the third dielectric layer 53 is greater than 300 nm, it may significantly debilitate the effect of enhancing performance of the gallium nitride-based device by the recessed field plate 70.

It should be understood that a relationship between the thickness of the third dielectric layer 53 and the thickness of the second dielectric layer 52, and a size of the field plate receiving groove 71 should be set to satisfy the requirement of forming the insulation groove 531 after the deposition of the third dielectric layer 53 in the field plate receiving groove 71.

Moreover, in this embodiment, a contact portion of the third dielectric layer 53 that is located in the field plate receiving groove 71 and that is in contact with the epitaxial layer 20 has a length in a first direction (a) ranging from 0.1 μm to 2 μm (see FIG. 11). The source electrode 30 and the drain electrode 40 are spaced from each other in the first direction (a). Referring to FIG. 11, “d₂” denotes the length of the contact portion of the third dielectric layer 53 that is located in the field plate receiving groove 71 (see FIG. 8) and that is in contact with the epitaxial layer 20 along the first direction (a), i.e., a width of the field plate receiving groove 71 along the first direction (a). When the length (d₂) is less than 0.1 μm, the electric field control performance of a sinking portion of the field plate 70 becomes poor; when the length (d₂) is greater than 2 μm, although the electric field control performance is improved, source-drain parasitic capacitance may become increased, which may adversely affect the radio-frequency performance.

In other embodiments, the length (d₂) may be, but not limited to, 0.1 μm, 0.5 μm, 1 μm, or 2 μm.

A shortest distance from the contact portion of the third dielectric layer 53 to the gate electrode 60 ranges from 0.1 μm to 2 μm. Referring to FIG. 11, “d₁” denotes the shortest distance from the contact portion of the third dielectric layer 53 that is located in the field plate receiving groove 71 and that is in contact with the epitaxial layer 20 to the gate electrode 60, i.e., a shortest distance between the gate receiving groove 61 (see FIG. 7) and the field plate receiving groove 71 along the first direction (a). When the field plate 70 serves as the source field plate and the shortest distance (d₁) is decreased to be less than 0.1 μm, which means a distance between the gate electrode 60 and the source electrode 30 becomes smaller, gate-source parasitic capacitance is increased, and processing difficulty is increased as well; when the shortest distance (d₁) is greater than 2 μm, the electric field control performance of the sinking portion of the field plate 70 may become worse.

In other embodiments, the shortest distance (d₁) may be, but not limited to, 0.1 μm, 0.5 μm, 1 μm, or 2 μm.

In certain embodiments, a material of the third dielectric layer 53 may be SiN, SiO, SiON, AlO, AlN, or AlON.

The third dielectric layer 53 may be a single-layer structure or a stacked structure, and may be made of various dielectric materials, such as SiN, SiO, AlO, and so forth. In the present disclosure, by providing the third dielectric layer 53, a depth of the field plate receiving groove 71 can be controlled by controlling a deposition thickness of the third dielectric layer 53, so that the depth of the field plate receiving groove 71 is not affected by etching uniformity, and can be corrected to a certain degree with provision of the third dielectric layer 53, thereby improving the accuracy of the field plate 70.

Referring to FIG. 10, in step (e2), the field plate 70 is formed in the insulation groove 531 (see FIG. 9), and the field plate 70 and the epitaxial layer 20 are insulated from each other by the third dielectric layer 53 formed in the field plate receiving groove 71 (see FIG. 8).

Specifically, in step (e2) of this embodiment, forming the field plate 70 in the insulation groove 531 can be implemented as follows.

Referring to FIG. 10, the field plate 70 is caused to sink into the insulation groove 531 so as to form a field plate recess 72 within the insulation groove 531, and two opposite sides of the field plate 70 are caused to extend outwards from the insulation groove 531 toward the gate electrode 60 and the drain electrode 40, respectively, so as to partially cover an upper surface of the third dielectric layer 53.

As shown in FIG. 10, the field plate 70 is located on the upper surface of the third dielectric layer 53, and includes a first portion located above the insulation groove 531, a second portion located on a side wall surface of the insulation groove 531, and a third portion located on a bottom surface of the insulation groove 531. The aforesaid three portions are continuously and integrally formed.

The field plate 70 of the present disclosure is in continuous contact with the bottom surface and the side wall surface of the insulation groove 531, so that no gap is formed between the field plate 70 and a side of the insulation groove 531 approximate to the gate electrode 60. As a result, the field plate 70 of the present disclosure shows a better electric field control performance, and hence the reliability of the gallium nitride-based device is improved. If there is a gap between the field plate 70 and the side of the insulation groove 531 approximate to the gate electrode 60, the electric field control capability of the field plate 70 at the gap is decreased, which may cause an increase of the peak electric field around an edge area of the gate electrode 60 approximate to the drain electrode 40, thereby posing a reliability risk, increasing the gate-drain parasitic capacitance Cgd, and hence reducing the radio-frequency gain thereof.

In this embodiment, an orthographic projection of the field plate 70, which is disposed on the upper surface of the third dielectric layer 53, on the substrate 10 partially covers the gate electrode 60.

The field plate recess 72 has a length in the first direction (a) ranging from 0.05 μm to 1.95 μm, and the source electrode 30 and the drain electrode 40 are spaced from each other in the first direction (a).

The first portion of the field plate 70 has a length in the first direction (a) ranging from 0.05 μm to 1 μm, and is located above the insulation groove 531 and extends outwards from the insulation groove 531 toward the drain electrode 40 so as to lie on top of the third dielectric layer 53. As shown in FIG. 11, “d₃” denotes the length of the first portion along the first direction (a). It should be noted that when the length (d₃) is less than 0.05 μm, it may cause manufacturing difficulties; when the length (d₃) is greater than 1 μm, it may result in an increase in the source-drain parasitic capacitance, which is not conducive to the radio-frequency performance.

Examples of the length (d₃) may be, but not limited to, 0.05 μm, 0.1 μm, 0.5 μm, or 1 μm.

The third portion of the field plate 70 that covers the bottom surface of the insulation groove 531 has a thickness ranging from 30 nm to 300 nm; for instance, the thickness may be, but not limited to, 30 nm, 100 nm, or 300 nm.

The second portion of the field plate 70 that covers the side wall surface of the insulation groove 531 has a thickness ranging from 30 nm to 300 nm; for example, the thickness may be, but not limited to, 30 nm, 100 nm, or 300 nm.

In summary, the method for manufacturing the gallium nitride-based device according to the present disclosure includes the steps of: (a) forming the epitaxial layer 20 on the substrate 10, forming the source electrode 30 and the drain electrode 40 spaced apart from each other on the epitaxial layer 20, and forming the first dielectric layer 51 between the source electrode 30 and the drain electrode 40 on the epitaxial layer 20; (b) forming the second dielectric layer 52 on the first dielectric layer 51, the second dielectric layer 52 covering the source electrode 30 and the drain electrode 40; (c) etching the first dielectric layer 51 and the second dielectric layer 52, so as to simultaneously form the gate receiving groove 61 and the field plate receiving groove 71 that expose the epitaxial layer 20 between the source electrode 30 and the drain electrode 40, the gate receiving groove 61 being disposed between the source electrode 30 and the field plate receiving groove 71; (d) forming the gate electrode 60 in the gate receiving groove 61; and (e) forming the field plate 70 in the field plate receiving groove 71, the field plate 70 being insulated from the epitaxial layer 20. By using the same photomask to form the gate receiving groove 61 and the field plate receiving groove 71 simultaneously, on the one hand, the manufacturing process can be simplified, thereby reducing the process complexity and improving the manufacturing efficiency of the gallium nitride-based device; on the other hand, the distance between the gate receiving groove 61 and the field plate receiving groove 71 can be determined by the corresponding distance designed on the patterned photomask; this distance is irrelevant to the alignment shift that occurs during photolithography, which is likely to happen in a conventional manufacturing process where two grooves are formed by two etching processes, respectively. As a result, the alignment accuracy of the gate electrode 60 and the field plate 70 can be improved, thereby improving the stability of the gallium nitride-based device.

According to the present disclosure, a gallium nitride-based device is also provided. Referring to FIG. 10, the gallium nitride-based device includes a substrate 10, an epitaxial layer 20 disposed on the substrate 10, a source electrode 30 and a drain electrode 40 disposed on the epitaxial layer 20 and spaced apart from each other, a gate electrode 60 disposed on the epitaxial layer 20 and between the source electrode 30 and the drain electrode 40, a first dielectric layer 51 disposed on the epitaxial layer 20, isolating the source electrode 30 from the gate electrode 60, and isolating the gate electrode 60 from the drain electrode 40, a second dielectric layer 52 disposed on the first dielectric layer 51, and covering the source electrode 30 and the drain electrode 40, and a field plate 70 disposed between the gate electrode 60 and the drain electrode 40. Moreover, the second dielectric layer 52 and the first dielectric layer 51 cooperatively define the field plate receiving groove 71 that extends through the second dielectric layer 52 and the first dielectric layer 51 to expose the epitaxial layer 20. The gate electrode 60 is exposed from the second dielectric layer 52. The field plate receiving groove 71 is disposed between the gate electrode 60 and the drain electrode 40. The field plate 70 is disposed in the field plate receiving groove 71 and sinks into the field plate receiving groove 71 to form a field plate recess 72. Additionally, the field plate 70 is insulated from the epitaxial layer 20.

Reference may be made to FIG. 6 for the appearance of the aforesaid field plate receiving groove 71, and reference may be made to the above description for the process regarding the formation of the field plate receiving groove 71 and the field plate recess 72.

As shown in FIG. 10, in certain embodiments, the gallium nitride-based device may further include a third dielectric layer 53 disposed between the second dielectric layer 52 and the field plate 70. The third dielectric layer 53 covers the second dielectric layer 52 and the gate electrode 60. The third dielectric layer 53 sinks into the field plate receiving groove 71 to cover a side wall surface and a bottom surface of the field plate receiving groove 71 and to form an insulation groove 531 inside the field plate receiving groove 71. The field plate 70 is disposed on the third dielectric layer 53. A portion of the field plate 70 sinks into the insulation groove 531 to form the field plate recess 72. In other words, the field plate recess 72 is located inside the insulation groove 531. An orthographic projection of the field plate 70 on the substrate 10 partially covers the gate electrode 60.

In the present disclosure, by providing the third dielectric layer 53, a depth of the field plate receiving groove 71 can be controlled by controlling a deposition thickness of the third dielectric layer 53, so that the depth of the field plate receiving groove 71 is not affected by etching uniformity, and can be corrected to a certain degree with provision of the third dielectric layer 53, thereby improving the accuracy of the field plate 70.

It should be noted that the gallium nitride-based device according to the disclosure can be prepared by the method for manufacturing the gallium nitride-based device revealed in the description above, which has been clearly stated and will not be described in detail hereinafter.

Furthermore, it is worthwhile to note that the thickness and material(s) of each structure of the gallium nitride-based device can be found correspondingly in the description of the aforementioned method, and therefore will not be repeated hereinafter.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a gallium nitride-based device, comprising the steps of:
(a) forming an epitaxial layer on a substrate, forming a source electrode and a drain electrode spaced apart from each other on the epitaxial layer, and forming a first dielectric layer between the source electrode and the drain electrode on the epitaxial layer;
(b) forming a second dielectric layer on the first dielectric layer, the second dielectric layer covering the source electrode and the drain electrode;
(c) etching the first dielectric layer and the second dielectric layer, so as to simultaneously form a gate receiving groove and a field plate receiving groove that expose the epitaxial layer between the source electrode and the drain electrode, the gate receiving groove being disposed between the source electrode and the field plate receiving groove;
(d) forming a gate electrode in the gate receiving groove; and
(e) forming a field plate in the field plate receiving groove, the field plate being insulated from the epitaxial layer.

2. The method as claimed in claim 1, wherein step (d) includes:
(d1) coating a first photoresist layer on the second dielectric layer, and patterning the first photoresist layer, so as to form a first through hole, the first through hole and the gate receiving groove being concentrically arranged, an orthographic projection of the first through hole on the substrate entirely covering the gate receiving groove; and
(d2) forming a metal layer on the first photoresist layer and in the gate receiving groove and the first through hole by vapor deposition, and removing the first photoresist layer, so as to obtain the gate electrode disposed in the gate receiving groove and the first through hole.

3. The method as claimed in claim 2, wherein step (e) includes:
(e1) continuously forming a third dielectric layer on the second dielectric layer and the gate electrode and in the field plate receiving groove, the third dielectric layer sinking into the field plate receiving groove and defining an insulation groove inside the field plate receiving groove; and
(e2) forming the field plate in the insulation groove, the field plate and the epitaxial layer being insulated from each other by the third dielectric layer formed in the field plate receiving groove.

4. The method as claimed in claim 3, wherein step (e2) includes:
causing the field plate to sink into the insulation groove so as to form a field plate recess within the insulation groove, and causing two opposite sides of the field plate to extend outwards from the insulation groove toward the gate electrode and the drain electrode, respectively, so as to partially cover an upper surface of the third dielectric layer.

5. The method as claimed in claim 3, wherein a material of the third dielectric layer is silicon nitride (SiN), silicon oxide (SiO), silicon oxynitride (SiON), aluminum oxide (AlO), aluminum nitride (AlN), or aluminum oxynitride (AlON).

6. The method as claimed in claim 1, wherein a material of the second dielectric layer is SiN, SiO, SiON, AlO, AlN, or AlON.

7. The method as claimed in claim 1, wherein the first dielectric layer has a thickness ranging from 1 nm to 150 nm.

8. The method as claimed in claim 1, wherein the second dielectric layer has a thickness ranging from 1 nm to 150 nm.

9. The method as claimed in claim 1, wherein the epitaxial layer includes at least one barrier layer and at least one gallium nitride (GaN) layer which cooperatively form a heterojunction.

10. The method as claimed in claim 1, wherein, in step (c), the gate receiving groove and the field plate receiving groove are formed using a same photomask.

11. The method as claimed in claim 2, wherein the first through hole is greater in size than the gate receiving groove.

12. A gallium nitride-based device, comprising:
a substrate;
an epitaxial layer disposed on said substrate;
a source electrode and a drain electrode disposed on said epitaxial layer and spaced apart from each other;
a gate electrode disposed on said epitaxial layer and between said source electrode said drain electrode;
a first dielectric layer disposed on said epitaxial layer, isolating said source electrode from said gate electrode, and isolating said gate electrode from said drain electrode;
a second dielectric layer disposed on said first dielectric layer, and covering said source electrode and said drain electrode; and
a field plate disposed between said gate electrode and said drain electrode,
wherein said gate electrode is exposed from said second dielectric layer, said second dielectric layer and said first dielectric layer cooperatively defining a field plate receiving groove that extends through said second dielectric layer and said first dielectric layer to expose said epitaxial layer, said field plate receiving groove being disposed between said gate electrode and said drain electrode, said field plate being disposed in said field plate receiving groove and sinking into said field plate receiving groove to form a field plate recess, said field plate being insulated from said epitaxial layer.

13. The gallium nitride-based device as claimed in claim 12, further comprising a third dielectric layer disposed between said second dielectric layer and said field plate, said third dielectric layer covering said second dielectric layer and said gate electrode, said third dielectric layer sinking into said field plate receiving groove to cover a side wall surface and a bottom surface of said field plate receiving groove and to form an insulation groove inside said field plate receiving groove, said field plate being disposed on said third dielectric layer, a portion of said field plate sinking into said insulation groove to form said field plate recess, an orthographic projection of said field plate on said substrate partially covering said gate electrode.

14. The gallium nitride-based device as claimed in claim 13, wherein a contact portion of said third dielectric layer that is located in said field plate receiving groove and that is in contact with said epitaxial layer has a length in a first direction ranging from 0.1 μm to 2 μm, said source electrode and said drain electrode being spaced from each other in the first direction.

15. The gallium nitride-based device as claimed in claim 14, wherein a shortest distance from said contact portion of said third dielectric layer to said gate electrode ranges from 0.1 μm to 2 μm.

16. The gallium nitride-based device as claimed in claim 13, wherein said field plate recess has a length in a first direction ranging from 0.05 μm to 1.95 μm, said source electrode and said drain electrode being spaced from each other in the first direction.

17. The gallium nitride-based device as claimed in claim 16, wherein said field plate has a first portion that has a length in the first direction ranging from 0.05 μm to 1 μm and that is located above said insulation groove and that extends outwards from said insulation groove toward said drain electrode so as to lie on top of said third dielectric layer.

18. The gallium nitride-based device as claimed in claim 13, wherein said third dielectric layer has a thickness ranging from 30 nm to 300 nm.

19. The gallium nitride-based device as claimed in claim 12, wherein said gate electrode is a stacked structure, said stacked structure including a nickel layer and a gold layer disposed on said nickel layer.

20. The gallium nitride-based device as claimed in claim 12, wherein said field plate is a stacked structure, said stacked structure sequentially including a first titanium layer, a platinum layer, a gold layer, and a second titanium.
